(19) United States
(12) Patent Application Publication
(10) Pub. No.: US 2012/0206663 A1
(43) Pub. Date: Aug. 16, 2012

(54) TELEVISION AND ELECTRONIC APPARATUS

(75) Inventors: Seiji Hashimoto, Ome-shi (JP); Tomohiro Hamada, Tachikawa-shi (JP)

(73) Assignee: KABUSHIKI KAISHA TOSHIBA, Tokyo (JP)

(21) Appl. No.: 13/272,093

(22) Filed: Oct. 12, 2011

(30) Foreign Application Priority Data
Feb. 14, 2011 (JP) 2011-028705

(51) Int. Cl. H04N 5/64; H05K 7/00

(52) U.S. Cl. 348/836; 361/679.01; 348/E05.128

(57) ABSTRACT

According to one embodiment, an electronic apparatus includes a housing including a first surface and a second surface opposite the first surface. The first surface includes a protrusion. The second surface includes a first recess opposite the protrusion and a second recess adjacent to the first recess. The second recess has substantially the same shape as the first recess.

### CROSS-REFERENCE TO RELATED APPLICATIONS

This application is based upon and claims the benefit of priority from prior Japanese Patent Application No. 2011-028705, filed Feb. 14, 2011, the entire contents of which are incorporated herein by reference.

### FIELD

Embodiments described herein relate generally to a television and an electronic apparatus each including a housing.

### BACKGROUND

There is known an electronic apparatus including a housing provided with a groove in a part thereof.

### BRIEF DESCRIPTION OF THE DRAWINGS

A general architecture that implements the various features of the embodiments will now be described with reference to the drawings. The drawings and the associated descriptions are provided to illustrate the embodiments and not to limit the scope of the invention.

FIG. 1 is an exemplary front view of a television according to a first embodiment.

FIG. 2 is an exemplary perspective view illustrating a part of the television illustrated in FIG. 1.

FIG. 3 is an exemplary cross-sectional view illustrating a housing of the television illustrated in FIG. 1.

FIG. 4 is an exemplary plan view of an electronic apparatus according to a second embodiment.

FIG. 5 is an exemplary perspective view of the electronic apparatus illustrated in FIG. 4.

FIG. 6 is an exemplary perspective view illustrating a groove of a housing illustrated in FIG. 5.

FIG. 7 is an exemplary cross-sectional view of the housing taken along the line F7-F7 of FIG. 6.

FIG. 8 is an exemplary rear view of the housing illustrated in FIG. 7 as seen from the direction of the arrow F8.

FIG. 9 is an exemplary cross-sectional view of the housing taken along the line F9-F9 in FIG. 8.

FIG. 10 is an exemplary cross-sectional view illustrating a modification of the housing illustrated in FIG. 9.

FIG. 11 is an exemplary perspective view illustrating a part of a housing of an electronic apparatus according to a third embodiment.

FIG. 12 is an exemplary plan view of the housing illustrated in FIG. 11.

### DETAILED DESCRIPTION

Various embodiments will be described hereinafter with reference to the accompanying drawings.

In general, according to one embodiment, an electronic apparatus comprises a housing comprising a first surface and a second surface opposite the first surface. The first surface comprises a protrusion. The second surface comprises a first recess opposite the protrusion and a second recess adjacent to the first recess. The second recess has substantially the same shape as the first recess.

Hereinafter, embodiments will be described with reference to the drawings.

### First Embodiment

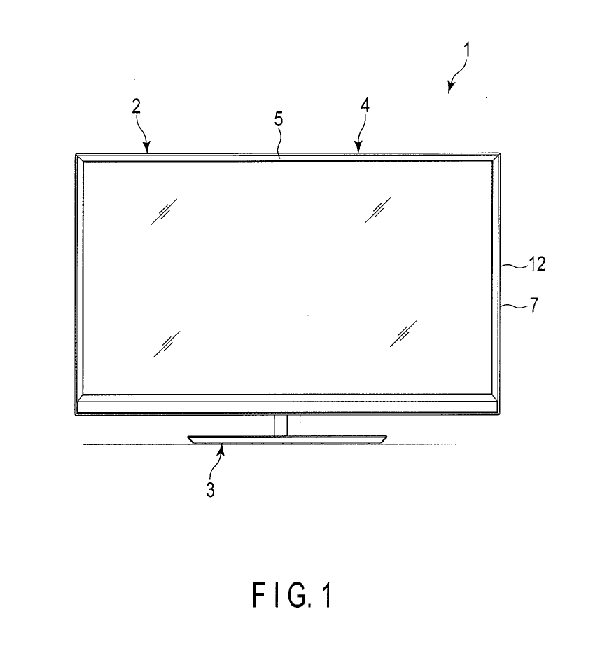

FIGS. 1 to 3 illustrate a television 1 according to a first embodiment. The television 1 is an example of an electronic apparatus. Examples of the electronic apparatus to which the present embodiment can be applied are not limited to the television, but include various electronic apparatuses, such as a notebook-type portable computer (notebook PC), a slate-type portable computer (slate PC), a cellular phone, a smart phone, a personal digital assistant (PDA), and a game machine.

As illustrated in FIG. 1, the television 1 includes a display unit 2 and a stand 3. The stand 3 is placed on a television table, for example. The display unit 2 is formed in a flat shape and is supported on the stand 3 in a state of standing substantially vertically.

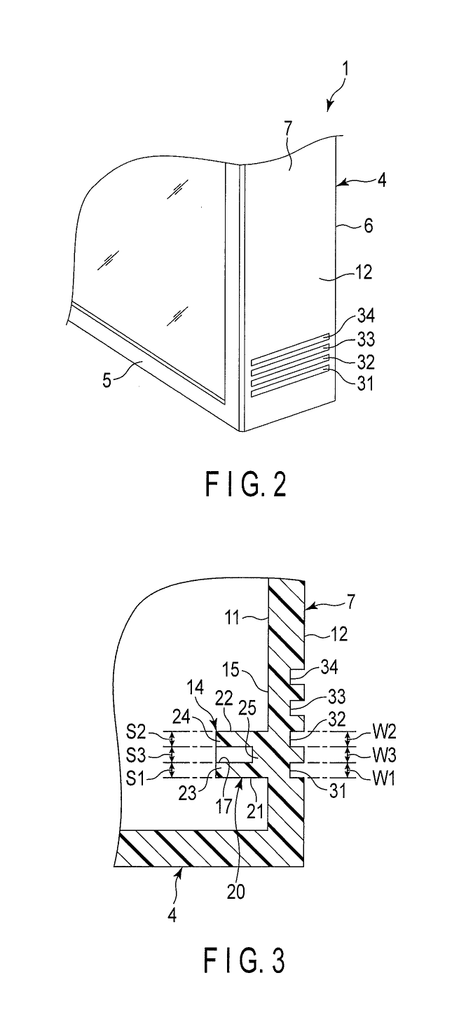

As illustrated in FIGS. 1 and 2, the display unit 2 includes a housing 4. The housing 4 includes a front wall 5, a rear wall 6, and a circumferential wall 7. The front wall 5 stands substantially vertically and faces users. The rear wall 6 is disposed on the opposite side from the front wall 5 and stands substantially vertically to be substantially parallel to the front wall 5. The circumferential wall 7 connects the peripheral portion of the front wall 5 and the peripheral portion of the rear wall 6.

As illustrated in FIGS. 2 and 3, the housing 4 includes a first surface 11 and a second surface 12. The first surface 11 is an inner surface that is exposed to the inside of the housing 4. The second surface 12 is an outer surface (external surface) disposed on the opposite side (back side) from the first surface 11 and exposed to the outside of the housing 4.

As illustrated in FIG. 3, the first surface 11 includes a boss 14 and a planar portion 15 (flat portion). The boss 14 is an example of a “protrusion.” In addition, the “protrusion” is not limited to the boss, and examples thereof may include a rib and other shapes. The boss 14 protrudes from the first surface 11 toward the inside of the housing 4. The boss 14 is a screwing boss, for example, and includes a threaded screw hole 17. The screw hole 17 is open at the leading end of the boss 14 and extends in the axial direction of the boss 14.

A circumferential surface 20 of the boss 14 includes a first side 21 and a second side 22 opposite the first side 21. That is, the second side 22 is disposed at a position rotated by substantially 180° from the first side 21 along the circumferential surface 20 of the boss 14.

The boss 14 includes a first portion 23, a second portion 24, and a third portion 25. The first portion 23 is disposed between the first side 21 and the screw hole 17. The second portion 24 is disposed between the second side 22 and the screw hole 17. The third portion 25 is a portion where the screw hole 17 is formed, and is disposed between the first portion 23 and the second portion 24. The third portion 25 is lower in terms of height (that is, thinner) from the first surface 11 than the first and second portions 23 and 24 by a distance corresponding to the screw hole 17.

The planar portion 15 is a region provided with no protrusion, such as a boss and has a flat surface which extends evenly. In this way, the thickness of the housing 4 is large in the region provided with the boss 14 but is small in the region of the planar portion 15 as compared to the region provided with the boss.

As illustrated in FIGS. 2 and 3, for example, the second surface 12 of the circumferential wall 7 is provided with four grooves 31, 32, 33, and 34. The grooves 31, 32, 33, and 34 include a first groove 31, a second groove 32, a third groove 33, and a fourth groove 34, respectively. The second groove 32 is an example of a “first recess.” The third groove 33 is an example of a “second recess.” The third groove 33 is provided near the second groove 32. The second groove 32 is provided near the first groove 31.

The first and second grooves 31 and 32 are provided on the second surface 12 at a position corresponding to the boss 14. That is, the first and second grooves 31 and 32 are provided on the opposite side (back side) from the boss 14. In addition, the “corresponding position” means that two elements overlap (namely face) each other in the thickness direction of a wall (in the present embodiment, the circumferential wall 7) of the housing.

As illustrated in FIG. 3, the first groove 31 is provided at the position corresponding to the first portion 23 of the boss 14, namely on the opposite side from the first portion 23. The width W1 of the first groove 31 is, for example, substantially equal to the width S1 of the first portion 23. The second groove 32 is provided at the position corresponding to the second portion 24 of the boss 14, namely on the opposite side from the second portion 24. The width W2 of the second groove 32 is, for example, substantially equal to the width S2 of the second portion 24. The distance W3 between the first groove 31 and the second groove 32 is, for example, substantially equal to the width S3 of the third portion 25.

The third and fourth grooves 33 and 34 are provided on the second surface 12 at a position that does not correspond to the boss 14. The third and fourth grooves 33 and 34 are provided on the opposite side (back side) from the planar portion 15.

As illustrated in FIG. 2 and FIG. 3, the second groove 32 is adjacent to the first groove 31. The third groove 33 is adjacent to the second groove 32. The fourth groove 34 is adjacent to the third groove 33. The first to fourth grooves 31, 32, 33, and 34 are arranged at equal intervals and substantially in parallel to each other. The first to fourth grooves 31, 32, 33, and 34 are substantially identical in shape. The first to fourth grooves 31, 32, 33, and 34 are substantially identical in width, length, and depth. The first to fourth grooves 31, 32, 33, and 34 extend substantially in a linear shape in the thickness direction of the housing 4.

In addition, the first to fourth grooves 31, 32, 33, and 34 may be at least partially identical in shape. For example, only part of each of the third and fourth grooves 33 and 34 may be identical in shape to the first and second grooves 31 and 32. Moreover, only part of the second groove 32 may be identical in shape to the first groove 31.

The first to fourth grooves 31, 32, 33, and 34 are provided on the second surface 12 and are exposed to the outside of the housing 4. The first to fourth grooves 31, 32, 33, and 34 are regularly arranged so as to constitute part of the exterior design of the housing 4.

In addition, the total number of grooves provided on the second surface 12 may be two or three, or may be five or more. The number of grooves provided on the opposite side from the boss 14 may be one or may be three or more. Moreover, the number of grooves provided on the opposite side from the planar portion 15 may be one or may be three or more.

According to such a configuration, it is possible to improve the strength of the housing and to maintain and improve an aesthetic appearance of a product. That is, if a protrusion is formed on the inner surface of the housing, the thickness of the housing increases in that portion. If a partially thick portion is present on the surface, there is a possibility that a void is formed in that portion during molding and a depression is formed on the exterior surface of that portion. The depression on the exterior surface may affect the aesthetic appearance of a product.

Moreover, if a partially thick portion is present on the surface, the surface temperature of the product falls faster than the inner temperature of the product, and bubbles are likely to remain in the product. If bubbles remain in the product, there is a possibility that the strength of the housing decreases in that portion.

On the other hand, in the present embodiment, the housing 4 includes the first surface 11 on which the boss 14 is provided and the second surface 12 opposite the first surface 11. On the second surface 12 is provided a first recess (the second groove 32) opposite the boss 14 and a second recess (the third groove 33), which is substantially identical in shape to the first recess, near the first recess.

That is, the first recess is formed in the region facing the boss 14, and thus the thickness of the region facing the boss 14 is relatively small as compared with other regions due to the first recess. Therefore, the speed of the temperature decrease during molding in the region where the boss 14 is provided is similar to the speed of the temperature decrease in the region where the flat portion 15 is provided. Therefore, voids are hardly formed, and depressions or the like are hardly formed on the exterior surface. In this way, it is possible to improve the aesthetic appearance of the product.

If a recess is formed in the region facing the boss 14, molten metal near the recess is difficult to be cooled during molding, and bubbles are not likely to remain in the product. Thus, the strength of the housing 4 improves.

Here, the above effects may be obtained by providing the only one recess on the first surface 11, particularly at the position opposite from the protrusion. However, if the recess is provided only on the opposite position from the protrusion, there is a possibility that the recess is visible on the exterior appearance of the product.

Therefore, in the present embodiment, the second recess is provided near the first recess, and the second recess is substantially identical in shape to the first recess. Thus, the first and second recesses collaborate with each other to constitute a design (pattern) on the exterior surface of the housing 4. That is, the first and second recesses maintain or improve the aesthetic appearance of the product.

In other words, the first recess constituting part of the exterior design suppresses the occurrence of voids and bubbles, and the second recess provided near the first recess collaborates with the first recess, so that it is possible to provide the housing 4 having excellent design. In the present embodiment, in order to make the first recess opposite the protrusion visually unrecognizable, the second recess is formed at a position displaced from the protrusion, and these first and second recesses are made substantially identical in shape. By doing so, it is possible to suppress the occurrence of voids and bubbles and to improve the design properties.

In the present embodiment, the housing 4 includes the first surface 11 on which the boss 14 is provided, the second surface 12 disposed to be opposite from the first surface 11 and exposed to the outside, and the first to third grooves 31, 32, and 33 provided on the second surface 12. The first groove 31 is provided on the second surface 12 at the position corresponding to the boss 14. The second groove 32 is provided on the second surface 12 at the position corresponding to the boss 14 and is aligned with the first groove 31 while being substantially identical in shape to the first groove 31. The third groove 33 is provided on the second surface 12 at a position that does not correspond to the boss 14 and is aligned with the first and second grooves 31 and 32 while being identical in shape to the first groove 31.

According to this configuration, the first and second grooves 31 and 32 provided in the region facing the boss 14 act as the cause of reducing the thickness of the region facing the boss 14. Thus, the occurrence of voids and bubbles is suppressed. In addition, the third groove 33 is provided in the region that does not face the boss 14, and the first to third grooves 31, 32, and 33 are aligned with each other while being substantially identical in shape. The first to third grooves 31, 32, and 33 collaborate with each other to constitute a design on the exterior surface of the housing 4. That is, the first to third grooves 31, 32, and 33 suppress the occurrence of voids and bubbles and improve the aesthetic appearance of the product. In addition, some extent of improvement of the aesthetic appearance can be expected as long as the first to third grooves 31, 32, and 33 are at least partially identical in shape.

In the present embodiment, the first to third grooves 31, 32, and 33 are arranged at equal intervals and extend substantially in parallel to each other. According to this configuration, an excellent design having a periodic pattern can be formed on the exterior surface of the housing 4.

In the present embodiment, the third groove 33 is provided on the second surface 12 in the region facing the planar portion 15. That is, the third groove 33 provided in the region facing the planar portion 15 collaborates with the first and second grooves 31 and 32, whereby the housing 4 having a more complex and elaborate design can be provided.

In the present embodiment, the boss 14 includes the first portion 23 disposed between the first side 21 and the screw hole 17 and the second portion 24 disposed between the second side 22 and the screw hole 17. The first groove 31 is provided so as to correspond to the first portion 23 of the boss 14. The second groove 32 is provided so as to correspond to the second portion 24 of the boss 14. According to this configuration, since the first and second grooves 31 and 32 are provided so as to correspond to a thick portion (a portion excluding the screw hole) of the boss 14, voids can be suppressed more surely.

In the present embodiment, the first to third grooves 31, 32, and 33 extend substantially in a linear shape in the thickness direction of the housing 4. The housing 4 is pulled out of a mold in the thickness direction thereof during molding. If the first to third grooves 31, 32, and 33 extend substantially in a linear shape in the thickness direction of the housing 4, the housing can be easily pulled (removed) out of the mold.

### Second Embodiment

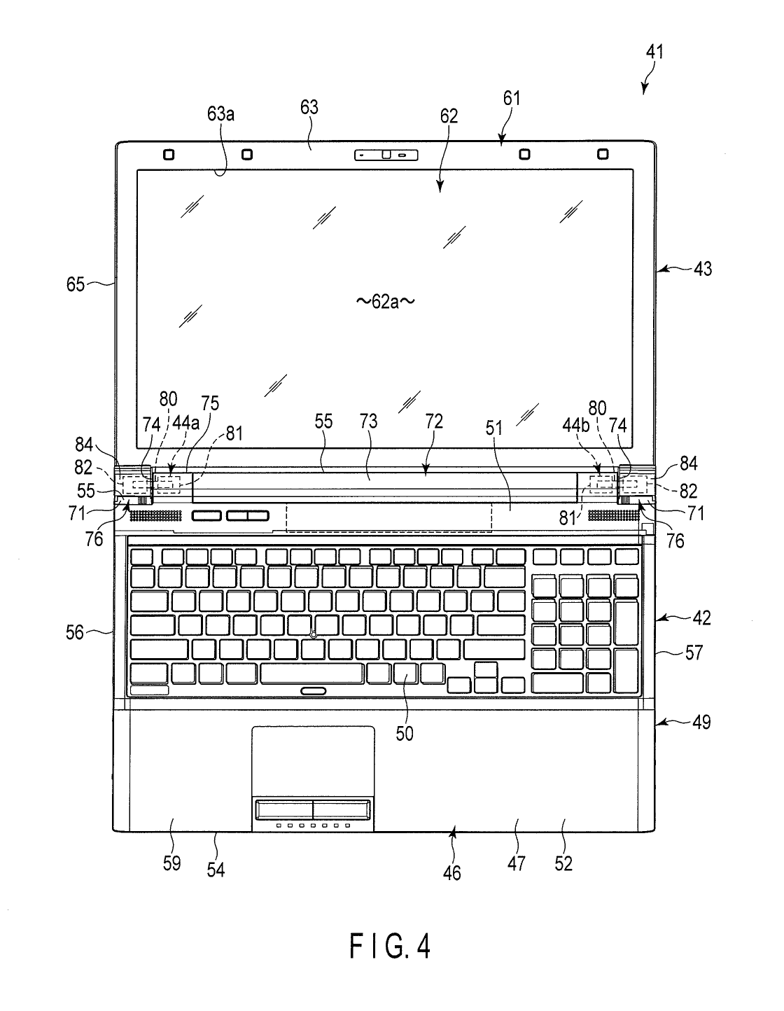

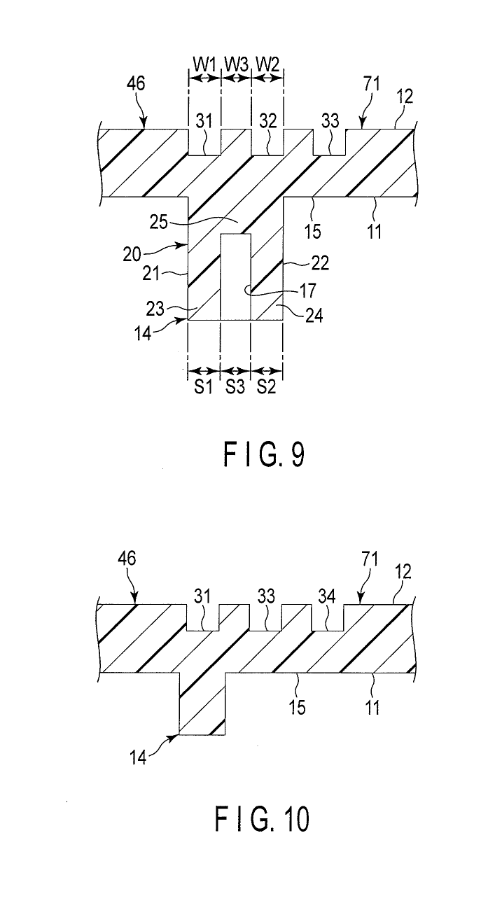

Next, an electronic apparatus 41 according to a second embodiment will be described with reference to FIGS. 4 to 9. Configurations having the same or similar functions as those of the first embodiment will be denoted by the same reference numerals, and a description thereof will not be repeated. Moreover, configurations other than those described below are the same as those of the first embodiment. The electronic apparatus 41 is a notebook PC, for example. The electronic apparatus to which the present embodiment can be applied is not limited to the notebook PC, but the present embodiment can be broadly applied to various electronic apparatuses as described above.

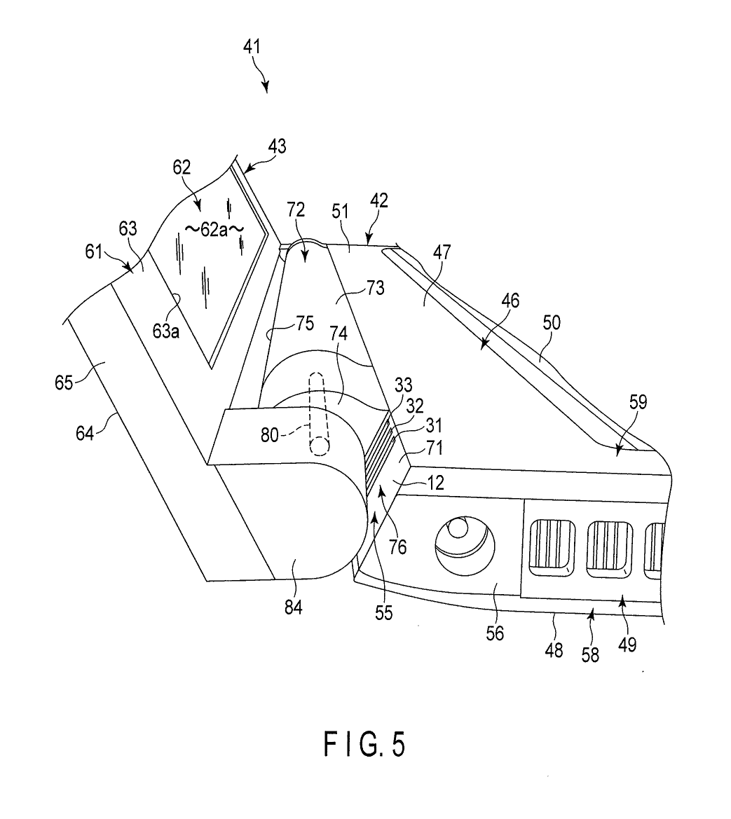

As illustrated in FIGS. 4 and 5, the electronic apparatus 41 includes a main unit 42 (first unit), a display unit 43 (second unit), and hinges 44a and 44b. The main unit 42 is an electronic apparatus body having a main board mounted therein. The main unit 42 includes a first housing 46. The first housing 46 includes an upper wall 47, a lower wall 48, and a circumferential wall 49 and has a flat box-like shape.

The lower wall 48 faces the surface of a desk when the electronic apparatus 41 is placed on the desk. The upper wall 47 extends substantially in parallel to the lower wall 48 with a space therebetween. The circumferential wall 49 stands on the lower wall 48, and connects the peripheral portion of the lower wall 48 to the peripheral portion of the upper wall 47. A keyboard 50 is attached to the upper wall 47. The keyboard 50 is an example of an “input portion.” In addition, the “input portion” (input receiving portion) may be a touch panel-type input device and may be other types of input devices.

The first housing 46 includes a rear end portion 51 (first end portion) and a front end portion 52 (second end portion). The display unit 43 is attached to the rear end portion 51 by the hinges 44a and 44b. The front end portion 52 is disposed on the opposite side from the rear end portion 51.

The circumferential wall 49 includes a front wall 54, a rear wall 55, a left side wall 56, and a right side wall 57. The front wall 54 is disposed on the front end portion 52 of the first housing 46 so as to extend in a horizontal width direction (left and right direction) of the first housing 46. The rear wall 55 is disposed on the rear end portion 51 so as to extend in the horizontal width direction of the first housing 46 substantially in parallel to the front wall 54. The left and right side walls 56 and 57 extend in a vertical width direction (front and read direction) of the first housing 46. The left and right side walls 56 and 57 connect the end portion of the front wall 54 and the end portion of the rear wall 55.

In this specification, the side closer to the user using the electronic apparatus 41 is defined as “front” and the side farther from the user is defined as “rear.” Moreover, the directions left and right are defined as seen from the user of the electronic apparatus 41.

As illustrated in FIG. 5, the first housing 46 includes a base 58 (first member) and a cover 59 (second member). The base 58 includes the lower wall 48 and a part of the circumferential wall 49. The cover 59 includes the upper wall 47 and a part of the circumferential wall 49. The cover 59 is combined with the base 58 to thereby form the first housing 46.

As illustrated in FIG. 4, the display unit 43 includes a second housing 61 and a display device 62 accommodated in the second housing 61. The display device 62 is a liquid crystal display, for example, but is not limited to thereto. The display device 62 includes a display screen 62a on which images and videos are displayed.

The second housing 61 is pivotably (openably) attached to the rear end portion 51 of the first housing 46 by the hinges 44a and 44b. In this way, the display unit 43 can pivot between a first position where it overlaps the main unit 42 and a second position where it stands with respect to the main unit 42.

As illustrated in FIG. 5, the second housing 61 includes a front wall 63, a back wall 64, and a circumferential wall 65. The front wall 63 faces the main unit 42 when the display unit 43 is at the first position. The front wall 63 includes an opening 63a through which the display screen 62a of the display device 62 is exposed. In other words, the second housing 61 can pivot between the first position where the display screen 62a is covered by the first housing 46 and the second position where the display screen 62a is exposed.

The back wall 64 extends substantially in parallel to the front wall 63 with a space therebetween. The back wall 64 faces the display device 62 at the opposite side from the front wall 63. The circumferential wall 65 stands on the back wall 64, and connects the peripheral portion of the front wall 63 and the peripheral portion of the back wall 64.

As illustrated in FIGS. 4 and 5, the rear end portion 51 of the first housing 46 includes rear end walls 71 which are parts of the first housing 46 and a first connecting portion 72 that protrudes further rearward from the rear end walls 71. Each of the rear end walls 71 is an example of a “wall.” The first connecting portion 72 is an example of a “first projection”.

The rear end walls 71 are formed on the left and right end portions of the first housing 46, respectively. The rear end wall 71 is part of the rear wall 55 and extends in the horizontal width direction (namely, the longitudinal direction) of the first housing 46. The rear end wall 71 faces the opposite side from the user, namely the rear side of the electronic apparatus 41. The rear end wall 71 faces in a direction opposite to the keyboard 50 (the input portion) from the rear end portion 51 of the first housing 46. The rear end wall 71 extends between the upper wall 47 and the lower wall 48. Moreover, the rear end wall 71 extends between the left side wall 56 (or the right side wall 57) and the first connecting portion 72.

The first connecting portion 72 is provided between a pair of rear end walls 71. The first connecting portion 72 protrudes from the rear end portion 51 of the first housing 46 in a direction opposite to the keyboard 50 (the input portion). The first connecting portion 72 is relatively long in the longitudinal direction of the first housing 46 and includes a battery 73 mounted thereon, for example.

As illustrated in FIG. 5, the first connecting portion 72 includes first walls 74 and a second wall 75. The first walls 74 are connected to the rear end wall 71 and extend in a direction crossing (for example, substantially perpendicular to) the rear end wall 71. The second wall 75 extends in the longitudinal direction of the first housing 46 so as to connect a pair of first walls 74 which are provided on the left and right end portions of the first housing 46, respectively.

In this way, a receiving portion 76 (hinge receiving portion) which is defined by the rear end wall 71 and the first wall 74 and in two directions is provided between the rear end wall 71 and the first wall 74 of the first connecting portion 72. The receiving portions 76 are cut-out portions which are formed at the left and right end portions of the first housing 46, respectively. In other words, the rear end wall 71 is provided at a position which is recessed from the second wall 75 of the first connecting portion 72 toward the keyboard 50 (the input portion) by a distance corresponding to the receiving portion 76.

As illustrated in FIG. 4, the hinges 44a and 44b include a hinge shaft 80 and first and second attaching portions 81 and 82 connected to the hinge shaft 80. The first attaching portion 81 is a main unit attaching bracket attached to the first housing 46. The second attaching portion 82 is a display unit attaching bracket attached to the second housing 61. The hinge shaft 80 extends in the longitudinal direction of the first housing 46 and pivotably connects the first and second attaching portions 81 and 82.

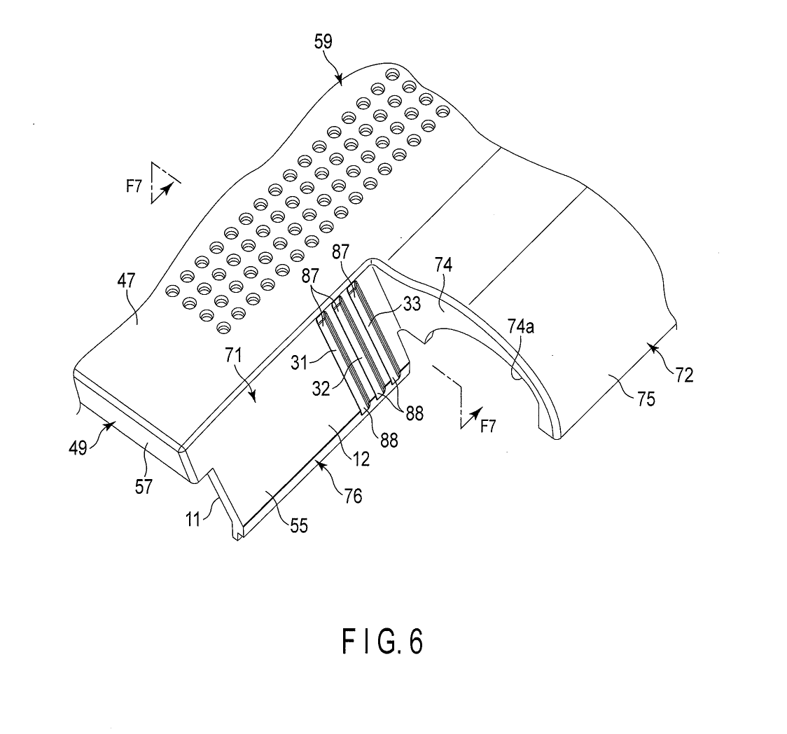

The rear end wall 71 extends in the axial direction of the hinge shaft 80. The first wall 74 of the first connecting portion 72 extends in the radial direction of the hinge shaft 80. As illustrated in FIG. 6, the first wall 74 includes a hole 74a through which the hinge shaft 80 is inserted.

As illustrated in FIG. 4, a pair of second connecting portions 84 is provided at the left and right end portions of the second housing 61. The second connecting portion 84 is an example of a “second protrusion.” The second connecting portion 84 protrudes from the second housing 61 toward the first housing 46. The second connecting portion 84 enters the receiving portions 76 provided at the left and right end portions of the first housing 46, respectively and are aligned with the first connecting portion 72 from the axial direction of the hinge shaft 80.

The first attaching portions 81 of the hinges 44a and 44b are attached to the first connecting portion 72. The second attaching portions 82 of the hinges 44a and 44b are attached to the second connecting portion 84. The hinges 44a and 44b pivotably connect the first and second connecting portions 72 and 84.

As illustrated in FIG. 5, the first wall 74 of the first connecting portion 72 faces the second connecting portion 84 in the axial direction of the hinge shaft 80. The rear end wall 71 faces the second connecting portion 84 in the radial direction of the hinge shaft 80. That is, the rear end wall 71 faces the second connecting portion 84 in a direction different from (for example, substantially perpendicular to) a direction in which the first connecting portion 72 faces the second connecting portion 84.

In other words, the rear end wall 71 is an example of a wall that faces the second housing 61. The rear end wall 71 is positioned at the end portion of the first housing 46 connected to the second housing 61 and is covered by the second housing 61. The rear end wall 71 is covered by the second housing 61, for example, at both a first position where the first and second housings 46 and 61 overlap each other and a second position where the first and second housings 46 and 61 are open.

As illustrated in FIGS. 5 to 9, the rear end wall 71 includes a first surface 11 and a second surface 12. The first surface 11 is the inner surface that is exposed to the inside of the first housing 46. The second surface 12 is the outer surface (external surface) that is disposed on the opposite side from the first surface 11 and exposed to the outside of the first housing 46. The second surface 12 faces the second connecting portion 84 in the radial direction of the hinge shaft 80.

The first surface 11 includes a boss 14 and a planar portion 15. The boss 14 is an example of a “protrusion.” In addition, the “protrusion” is not limited to the boss, and may be a rib or other shapes. The first and second surfaces 11 and 12 are inclined surfaces that are inclined with respect to the upper and lower walls 47 and 48. The boss 14 protrudes obliquely from the first surface 11. The boss 14 protrudes from the first surface 11 in a direction substantially perpendicular to the upper and lower walls 47 and 48, for example. In addition, the broken line in FIG. 8 schematically illustrates the boss 14.

As illustrated in FIGS. 5 to 9, for example, three grooves 31, 32, and 33 are formed on the second surface 12 of the rear end wall 71. The grooves 31, 32, and 33 include a first groove 31, a second groove 32, and a third groove 33. The second groove 32 is an example of a “first recess.” The third groove 33 is an example of a “second recess”.

In addition, the total number of grooves provided on the second surface 12 may be two or may be four or more. The number of grooves provided on the opposite side from the boss 14 may be one or may be three or more. Moreover, the number of grooves provided on the opposite side from the planar portion 15 may be two or more. FIG. 10 illustrates a modification in which only one groove 31 is formed to be opposite the boss 14.

The first and second grooves 31 and 32 are provided on the second surface 12 at the position corresponding to the boss 14. The first groove 31 is provided so as to correspond to the first portion 23 of the boss 14. The second groove 32 is provided so as to correspond to the second portion 24 of the boss 14.

The third groove 33 is provided on the second surface 12 at a position that does not correspond to the boss 14. The third groove 33 is provided to be opposite the planar portion 15. The third groove 33 is provided between the second groove 32 and the first wall 74 of the first connecting portion 72, for example.

As illustrated in FIGS. 6 and 8, the first to third grooves 31, 32, and 33 are arranged at equal intervals and substantially in parallel to each other. The first to third grooves 31, 32, and 33 are substantially identical in shape. The first to third grooves 31, 32, and 33 are regularly arranged so as to constitute part of the exterior design of the first housing 46.

As illustrated in FIG. 8, the first to third grooves 31, 32, and 33 extend in the inclined direction of the boss 14. That is, when seen from the direction vertical to the second surface 12, the first to third grooves 31, 32, and 33 extend in the longitudinal direction of the boss 14. Furthermore, the boss 14 protruding obliquely from the first surface 11 includes an elliptical boundary portion 86 (contact portion) disposed between the first surface 11 and the boss 14. The boundary portion 86 extends in the inclined direction of the boss 14, and the longitudinal direction thereof corresponds to the inclined direction of the boss 14. The first to third grooves 31, 32, and 33 extend in the longitudinal direction of the boundary portion 86.

The first to third grooves 31, 32, and 33 extend substantially in a linear shape in the thickness direction (namely, the direction where the first housing 46 is pulled out of a mold) of the first housing 46. The first to third grooves 31, 32, and 33 extend over both end portions of the first housing 46 in the thickness direction of the first housing 46. The first to third grooves 31, 32, and 33 extend over substantially the entire thickness of the cover 59 of the first housing 46, for example.

Specifically, as illustrated in FIG. 6, each of the first to third grooves 31, 32, and 33 includes a first end portion 87 and a second end portion 88 disposed to be opposite the first end portion 87. Strictly speaking, the first end portion 87 is not connected to the upper wall 47 but extends up to a position slightly lower than the upper end of the rear end wall 71 that is connected to the upper wall 47. With this configuration, the grooves 31, 32, and 33 are hardly seen from the user.

The second end portion 88 reaches the lower end of the cover 59 in the extension direction of the grooves 31, 32, and 33 and is open at the lower end of the cover 59. With this configuration, the housing can be more easily pulled (removed) out of the mold.

According to such a configuration, similarly to the first embodiment, it is possible to improve the strength of the housing and to maintain or improve the aesthetic appearance of a product.

In addition, in the present embodiment, the electronic apparatus 41 includes the first housing 46 including the first connecting portion 72, the second housing 61 including the second connecting portion 84 aligned with the first connecting portion 72, and the hinges 44a and 44b pivotably connecting the first and second connecting portions 72 and 84. The first housing 46 includes the rear end wall 71 facing the second connecting portion 84 in the direction different from the direction in which the first connecting portion 72 faces the second connecting portion 84, and the first to third grooves 31, 32, and 33 are provided on the rear end wall 71.

The rear end wall 71 is a portion that faces the second connecting portion 84 of the second housing 61. That is, the rear end wall 71 is disposed between the two housings 46 and 61 and is hardly seen from the user. With the configuration in which the first to third grooves 31, 32, and 33 are provided at the positions where they are hardly seen from the user, it is possible to suppress the occurrence of voids and bubbles while suppressing the presence of the grooves 31, 32, and 33 from being recognized.

In the present embodiment, the hinges 44a and 44b include the hinge shaft 80. The second surface 12 faces the second connecting portion 84 in the radial direction of the hinge shaft 80. The second surface 12 faces the second connecting portion 84 at both the first position where the first and second housings 46 and 61 are closed and at the second position where the first and second housings 46 and 61 are open. That is, the second surface 12 is covered by the second connecting portion 84 regardless of whether the display unit 43 is closed or open. When the first to third grooves 31, 32, and 33 are provided on the second surface 12, the grooves 31, 32, and 33 are more difficult to be seen from the user and are hardly recognizable.

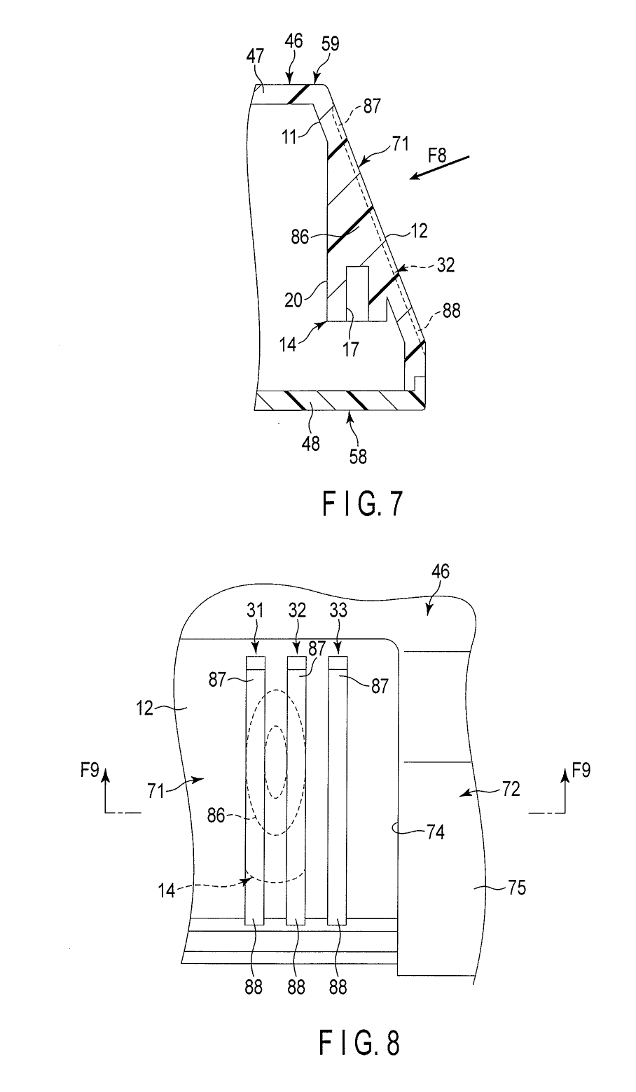

In the present embodiment, the boss 14 protrudes obliquely from the first surface 11. As illustrated in FIGS. 7 and 8, when the boss 14 is provided so as to protrude obliquely from the first surface 11, the boss 14 and the first surface 11 are connected over a relatively long distance in the inclined direction thereof, and the contact portion (the boundary portion 86) between the boss 14 and the first surface 11 increases in size. Thus, a thick portion is formed in the first housing 46 over a relatively long distance.

In the present embodiment, the first to third grooves 31, 32, and 33 are provided along the inclined direction of the boss 14. With this configuration, since the grooves 31, 32, and 33 extend along the longitudinal direction of the thick portion, the grooves 31, 32, and 33 can reduce the thickness of the thick portion over a relatively long range. In this way, it is possible to suppress voids more effectively.

In the present embodiment, the second surface 12 is provided at a position that is recessed from the first connecting portion 72 toward the input portion (the keyboard 50). The second surface 12 at such a recessed position is hardly seen from the user. When the first to third grooves 31, 32, and 33 are provided at the position where they are hardly seen from the user, it is possible to suppress the occurrence of voids and bubbles while suppressing the presence of the grooves 31, 32, and 33 from being recognized.

### Third Embodiment

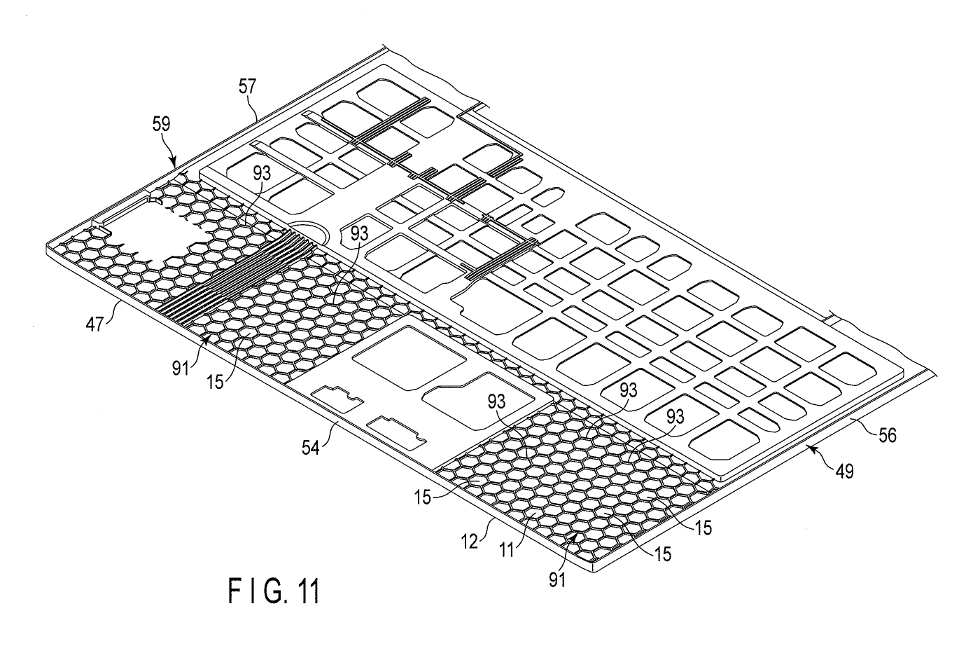

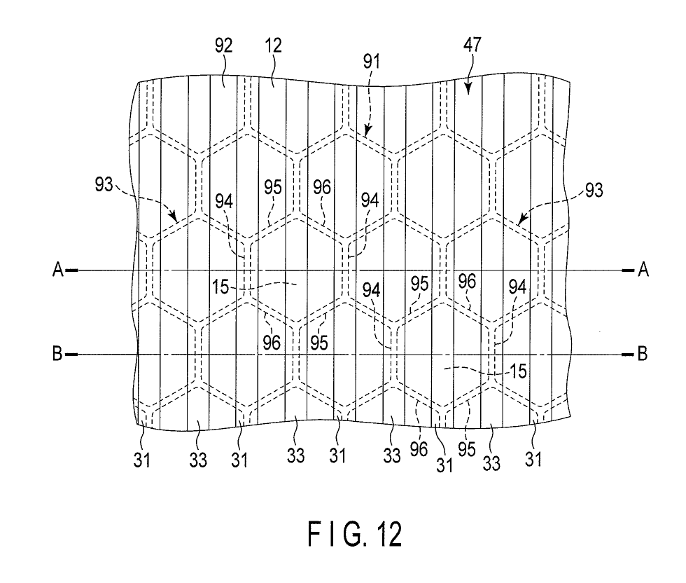

Next, an electronic apparatus 41 according to a third embodiment will be described with reference to FIGS. 11 and 12. Configurations having the same or similar functions as those of the first and second embodiments will be denoted by the same reference numerals, and a description thereof will not be repeated. Moreover, configurations other than those described below are the same as those of the second embodiment.

FIG. 11 illustrates an inner surface (a first surface 11) of a cover 59. Honeycomb ribs 91 are formed on the inner surface of the cover 59. The honeycomb ribs 91 are provided on the rear side of a palm rest 92, for example. The honeycomb ribs 91 are ribs that protrude inward the housing 46 from the first surface 11 and are formed by a set of hexagonal cells, for example. That is, the hexagonal cells 93 are densely arranged without any space.

As illustrated in FIG. 12, each cell 93 includes a first rib 94 extending in a first direction and a second rib 95 and a third rib 96 connected to the first rib 94 so as to extend in a second or third direction different from the first rib 94. The first rib 94 is an example of a “protrusion.” The first rib 94 extends in the lateral direction of a housing 46, for example. The first surface 11 of the housing 46 includes a planar portion 15 at a central portion of each cell 93 displaced from the first to third ribs 94, 95, and 96, for example.

As illustrated in FIG. 12, a plurality of grooves 31 and 33 are formed on the outer surface (the second surface 12) of the housing 46. The grooves 31 and 33 include the first groove 31 and the second groove 33. In the present embodiment, the first groove 31 is an example of a “first recess.” The second groove 33 is an example of a “second recess.” The first and second grooves 31 and 33 are provided alternately, for example. The second groove 33 is located near the first groove 31.

For example, when seen along the line A-A in FIG. 12, the first groove 31 is provided at the position corresponding to the first rib 94, namely on the opposite side from the first rib 94. The second groove 32 is provided at the position that does not correspond to the first rib 94, namely on the opposite side from the planar portion 15. On the other hand, when seen along the line B-B of FIG. 12, the first groove 31 is provided at the position that does not correspond to the first rib 94, namely on the opposite side from the planar portion 15. The second groove 33 is provided at the position corresponding to the first rib 94, namely on the opposite side from the first rib 94.

According to such a configuration, similarly to the first embodiment, it is possible to improve the strength of the housing and to maintain or improve the aesthetic appearance of a product.

The embodiment is not limited to the embodiments described above but may be realized by modifying constituent elements in implementing stage within a range without departing from the spirit of the invention. Moreover, various embodiments can be made by appropriately combining a plurality of constituent elements disclosed in the embodiments described above. For example, some constituent elements may be omitted from all the constituent elements disclosed in the embodiments. Furthermore, constituent elements in different embodiments may be combined appropriately.

For example, the grooves 31, 32, 33, and 34 may be provided on other positions such as the front wall 54, the side walls 56 and 57, the upper wall 47, or the lower wall 48 rather than the circumferential walls 7 and 49 of the housings 4 and 46. Moreover, the grooves 31, 32, 33, and 34 may be provided on the entire housing 4 or 46. The grooves 31, 32, 33, and 34 are not limited to the linear shape but may have a curved shape or other shapes. The sections of the grooves 31, 32, 33, and 34 may not be rectangular but may have a rounded shape or other shapes.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. An electronic apparatus comprising a housing, the housing comprising:
a first surface comprising a protrusion;
an exposed second surface opposite the first surface;
a first groove on the second surface at a position corresponding to the protrusion;
a second groove aligned with the first groove on the second surface, the second groove being at a position corresponding to the protrusion and having substantially the same shape as the first groove; and
a third groove on the second surface at a position that does not correspond to the protrusion, the third groove having substantially the same shape as the first groove and being aligned with the first and second grooves,
wherein the protrusion comprises a screw hole, a first side, a second side opposite the first side, a first portion between the first side and the screw hole, and a second portion between the second side and the screw hole, and
the first groove corresponds to the first portion of the protrusion, and the second groove corresponds to the second portion of the protrusion.

2. The electronic apparatus of claim 1,
wherein the first, second, and third grooves are spaced at substantially equal distances and extend substantially parallel to each other.

3. The electronic apparatus of claim 1,
wherein the first surface comprises a flat portion, and
the third groove is on the second surface at a position corresponding to the flat portion.

4. The electronic apparatus of claim 1,
wherein the protrusion is a boss.

5. The electronic apparatus of claim 1,
wherein the first, second, and third grooves extend substantially linearly in a thickness direction of the housing.

6. An electronic apparatus comprising:
a first housing comprising a first connecting portion;
a second housing comprising a second connecting portion adjacent to the first connecting portion; and
a hinge pivotally connecting the first and second connecting portions,
wherein the first housing comprises a wall facing the second connecting portion in a first direction different from a second direction in which the first connecting portion faces the second connecting portion, and
the wall comprises:
an inner first surface comprising a protrusion and a flat portion, the protrusion configured to receive a fixing member and comprising a portion configured to face a side of the fixing member;
an outer second surface opposite the first surface;
a first groove on the second surface at a position corresponding to the portion of the protrusion;
a second groove in a vicinity of the first groove on the second surface, the second groove being at a position corresponding to the protrusion and having substantially the same shape as the first groove; and
a third groove on the second surface at a position corresponding to the flat portion, the third groove and the first groove at least partially having substantially the same shape, the third groove being aligned with the first and second grooves.

7. The electronic apparatus of claim 6,
wherein the hinge comprises a hinge shaft, and
the second surface faces the second connecting portion in a radial direction of the hinge shaft and is configured to face the second connecting portion at both a first position where the first and second housings overlap each other and a second position where the first and second housings are open.

8. The electronic apparatus of claim 6,
wherein the protrusion protrudes obliquely from the first surface and comprises a boundary between the protrusion and the first surface, the boundary extending in an inclined direction of the protrusion, and
the first, second, and third grooves extend in a longitudinal direction of the boundary.

9. The electronic apparatus of claim 6,
wherein the first housing comprises an input portion, and
the second surface is recessed from the first connecting portion toward the input portion.

10. An electronic apparatus comprising a housing, the housing comprising:
a first surface comprising a protrusion, the protrusion configured to receive a fixing member and comprising a portion configured to face a side of the fixing member; and
a second surface opposite the first surface and comprising a first recess opposite the portion of the protrusion and a second recess in a vicinity of the first recess and opposite an area without the protrusion, the second recess having substantially the same shape as the first recess.

11. The electronic apparatus of claim 1, which is a television.
